(19) United States
(12) Patent Application Publication
(10) Pub. No.: US 2002/0151102 A1
(43) Pub. Date: Oct. 17, 2002

(54) Stacked semiconductor package structure having films and method for manufacturing the films

(76) Inventors: Jichen Wu, Hsinchu Hsien (TW); Meng Ru Tsai, Hsinchu Hsien (TW); Nai Hua Yeh, Hsinchu Hsien (TW); Chen Pin Peng, Hsinchu Hsien (TW); C.F. Wang, Hsinchu Hsien (TW); Wen Tsan Lee, Hsinchu Hsien (TW)

Correspondence Address: Keith Kline, PRO-TECHTOR INTERNATIONAL SERVICES, 20775 Norada Court, Saratoga, CA, 95070-3018, US

(21) Appl. No.: 09/836,159

(22) Filed: Apr. 16, 2001

(51) Int. Cl. H01L 21/44

(52) U.S. Cl. 438/106

(57) ABSTRACT

A method for manufacturing films used in semiconductor package, comprising the steps of: providing a frame having an upper surface and a lower surface opposite to the upper surface, a through-hole being formed in the frame; mounting a first covering layer onto the lower surface of the frame in order to covering the through-hole; placing a film into the through-hole of the frame, the film being adhered onto the first covering layer; providing a second covering layer for covering the frame and packing the film, the film being located between the first covering layer and the second covering layer; and cutting the film into a plurality of films each having a predetermined size by a cutting tool. The films after being cut may be placed between the lower semiconductor chip and the upper semiconductor chip, so that the plurality of wirings and the lower semiconductor chip are free from being short-circuited, and the bad signal transmission can be avoided.

### BACKGROUND OF THE INVENTION

1. Field of the Invention

The invention relates to a stacked semiconductor package structure having films and method for manufacturing the films, in particular, to a semiconductor package structure capable of preventing the semiconductor chips from being badly electrically connected or short-circuited and facilitating the manufacturing processes.

2. Description of the Related Art

To meet the demands of manufacturing small, thin, and light products, a lot of semiconductor chips can be stacked. However, when stacking a lot of semiconductor chips, the upper semiconductor chip will contact and press the wirings of the lower semiconductor chip. In this case, the signal transmission to or from the lower semiconductor chip is adversely influenced.

Referring to FIG. 1, a structure of stacked semiconductor chips includes a substrate 10, a lower semiconductor chip 12, an upper semiconductor chip 14, a plurality of wirings 16, and an isolation layer 18. The lower semiconductor chip 12 is located on the substrate 10. The isolation layer 18 is located on the lower semiconductor chip 12. The upper semiconductor chip 14 is stacked on the isolation layer 18. That is, the upper semiconductor chip 14 is stacked above the lower semiconductor chip 12 with the isolation layer 18 interposed between the semiconductor chips 12 and 14. Thus, a proper gap 20 is formed between the lower semiconductor chip 12 and the upper semiconductor chip 14. According to this structure, the plurality of wirings 16 can be electrically connected to the edge of the lower semiconductor chip 12. Furthermore, when stacking the upper semiconductor chip 14 above the lower semiconductor chip 12, the plurality of wirings 16 connecting the substrate 10 to the lower semiconductor chip 12 are free from being pressed, or the plurality of wirings 16 and the lower semiconductor chip 12 are free from being short-circuited.

However, the above-mentioned structure has the disadvantages to be described hereinbelow. During the manufacturing processes, the isolation layer 18 has to be manufactured in advance, and then, it is adhered to the lower semiconductor chip 12. Thereafter, the upper semiconductor chip 14 is adhered on the isolation layer 18. As a result, the manufacturing processes are complicated, and the manufacturing costs are high.

Furthermore, if the bonding pads of the lower semiconductor chip 12 are formed at the central portion thereof, it is impossible for the semiconductor chips to be stacked.

As shown in FIG. 2, bonding pads 22 are formed at the central portion of the lower semiconductor chip 23. In this case, the upper semiconductor chip 24 presses the wirings 25 to contact the edge of the lower semiconductor chip 23, thereby adversely influencing the signal transmission or causing the above-mentioned elements to be short-circuited.

To solve the above-mentioned problems, it is necessary for the invention to provide a stacked semiconductor package structure having films and method for manufacturing the same, in order to facilitate the manufacturing processes and lower down the manufacturing costs.

### SUMMARY OF THE INVENTION

It is therefore an object of the invention to provide a stacked semiconductor package structure having films and method for manufacturing the films, so as to facilitate the stacking processes of the integrated circuits and improve the manufacturing speed.

It is therefore another object of the invention to provide a stacked semiconductor package structure having films and method for manufacturing the films, so as to avoid bad signal transmission when stacking the semiconductor chips.

It is therefore still another object of the invention to provide a stacked semiconductor package structure having films and method for manufacturing the films, so as to prevent the wirings connected to the lower integrated circuit from being damaged by the upper integrated circuit, thereby facilitating the manufacturing processes.

It is therefore still another object of the invention to provide a stacked semiconductor package structure having films and method for manufacturing the films, so as to cut the film into a plurality of films each having a predetermined size used for stacking the semiconductor package structure.

To achieve the above object, the method for manufacturing films used in semiconductor package, comprising the steps of: providing a frame having an upper surface and a lower surface opposite to the upper surface, a through-hole being formed in the frame; mounting a first covering layer onto the lower surface of the frame in order to covering the through-hole; placing a film into the through-hole of the frame, the film being adhered onto the first covering layer; and cutting the film into a plurality of films each having a predetermined size by a cutting tool. By doing so, the films after being cut can be used for semiconductor package.

Further, the stacked semiconductor package structure of the invention is characterized in that the films after being cut are adhered onto the lower semiconductor chip. Thus, when the upper semiconductor chip is stacked on the lower semiconductor chip, the wirings are free from being pressed to be in electrical contact with the lower semiconductor chip. The conditions of short-circuiting and bad signal transmitting can be avoided.

### BRIEF DESCRIPTION OF THE DRAWINGS

FIG. 1 is a cross-sectional view showing a conventional stacked semiconductor package structure.

FIG. 2 is a schematic illustration showing another conventional stacked semiconductor package structure.

FIG. 3 is a first schematic illustration showing the method for manufacturing the films of the invention.

FIG. 4 is a second schematic illustration showing the method for manufacturing the films of the invention.

FIG. 5 is a third schematic illustration showing the method for manufacturing the films of the invention.

FIG. 6 is a cross-sectional view showing the stacked semiconductor package structure having films of the invention.

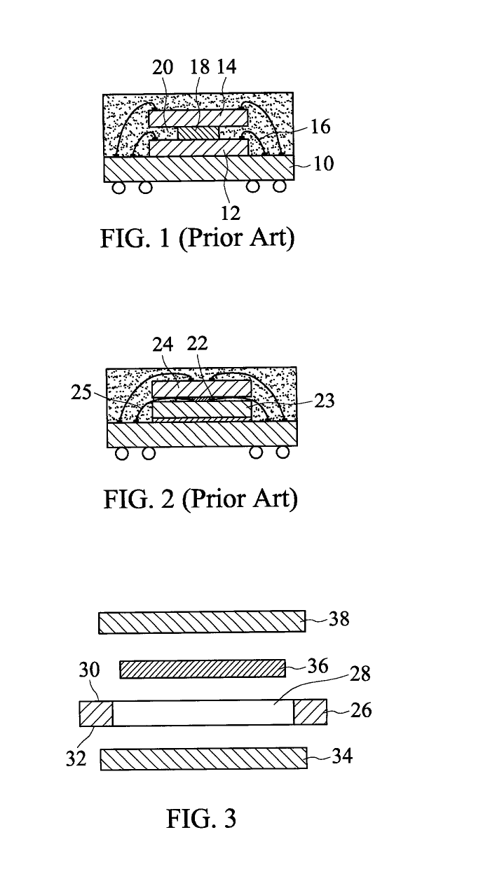

### DETAILED DESCRIPTION OF THE INVENTION

Referring to FIGS. 3 to 5, the method for manufacturing the films of the invention includes the following steps.

First, a frame 26 having an upper surface 30 and a lower surface 32 is provided. A through-hole 28 is formed in the frame 26.

Second, a first covering layer 34 is mounted onto the lower surface 32 of the frame 26 to cover the bottom of the through-hole 28.

Third, a film 36 having a predetermined size and is to be cut is placed into the through-hole 28 of the frame 26. The film 36 with adhesive property at its two sides is adhered onto the first covering layer 34.

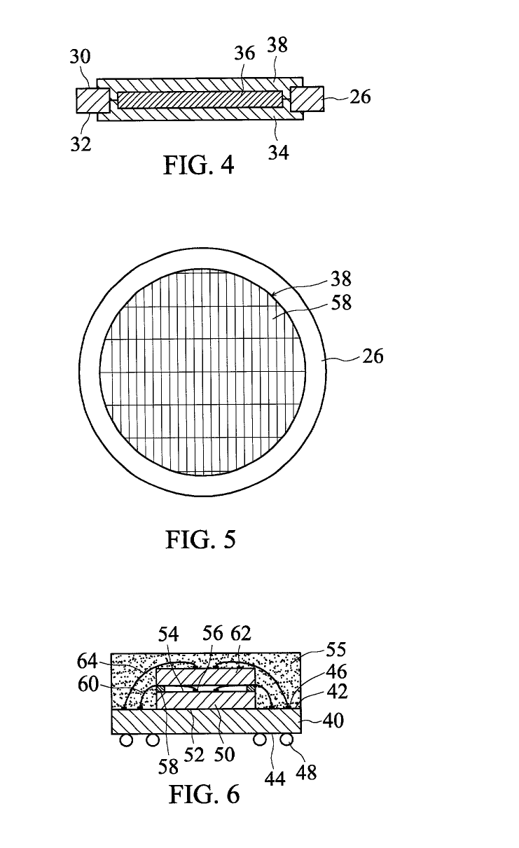

Fourth, a second covering layer 38 is mounted onto the frame 26 to cover the upper surface 30 of the frame 26 and to cover the through-hole 28. Thus, the film 36 located in the through-hole 28 is packed by the first covering layer 34 and the second covering layer 38, as show in FIG. 4. Further, since the film 36 is adhesive at its two sides, the film 36 may be adhered between the first covering layer 34 and the second covering layer 38.

Fifth, the frame 26 is fixed and a cutting tool is used for cutting the film 36 into a plurality of films 58. At this time, the second covering layer 38 is cut together with the film 36. The film 36 is cut to a predetermined depth while the first covering layer 34 is not cut. Therefore, the film 36 after being cut is still adhered onto the first covering layer 34.

The films 58 can be used to make the semiconductor chip adhere to the substrate according to their sizes. Furthermore, when stacking the semiconductor chips, the films 58 can also be adhered onto the lower semiconductor chip, so that the upper semiconductor chip can be stacked on the lower semiconductor chip. Thus, the upper semiconductor chip is free from breaking the wirings that are electrically connected to the lower semiconductor chip. Therefore, the short-circuited condition and the bad signal transmission can be avoided.

Referring to FIG. 6, the stacked semiconductor structure includes a substrate 40, a lower semiconductor chip 50, two films 58, a plurality of wirings 60, and an upper semiconductor chip 62.

The substrate 40 has a first surface 42 and a second surface 44. The first surface 42 is formed with signal input terminals 46 while the second surface 44 is formed with signal output terminals 48. The signal output terminals 48 may be metallic balls arranged in the form of a ball grid array for electrically connecting to a printed circuit board (not shown).

The lower semiconductor chip 50 has a lower surface 52 and an upper surface 54. The lower surface 52 is mounted onto the first surface 42 of the substrate 40. A plurality of bonding pads 56 are formed at the central portion of the upper surface 54.

The two films 58 are adhered onto the two sides of the upper surface 54 of the lower semiconductor chip 50.

One end of each of the plurality of wirings 60 is electrically connected to a corresponding one of the bonding pads 56 of the lower semiconductor chip 50, while the other end of the wiring 60 is electrically connected to a corresponding one of the signal input terminals 46 of the substrate 40.

The upper semiconductor chip 62 is placed above the upper surface 54 of the lower semiconductor chip 50 with the films 58 inserted therebetween, so that the upper semiconductor chip 62 can be stacked about the lower semiconductor chip 50.

Furthermore, an adhesive agent may be applied to places near the bonding pads 56 of the lower semiconductor chip 50, so as to further adhere the upper semiconductor chip 62 to the lower semiconductor chip 50. A plurality of wirings 64 may also be provided for electrically connecting the upper semiconductor chip 62 to the signal input terminals 46 of the substrate 40. A package layer 55 may also be provided on the first surface 42 of the substrate 40. for packing the lower semiconductor chip 50 and the upper semiconductor chip 62 and protecting the plurality of wirings 60 and 64.

When the upper semiconductor chip 62 is stacked above the lower semiconductor chip 50 and the wirings 60 is in contact with the upper semiconductor chip 62, the wirings 60 are free from being directly in contact with the lower semiconductor chip 50 by using the films 58. Thus, the wirings 60 and the lower semiconductor chip 50 are free from being short-circuited and the bad signal transmission can be avoided.

The stacked semiconductor package structure having films and the method for manufacturing the films have the following advantages.

1. When the upper semiconductor chip 62 is stacked above the lower semiconductor chip 50, the wirings 60 electrically connected to the lower semiconductor chip 50 are separated from the lower semiconductor chip 50 by the films 58. Although the wirings 60 are pressed by the upper semiconductor chip 62, the wirings 60 and the lower semiconductor chip 50 are free from being short-circuited.

2. The method for manufacturing the films of the invention is capable of cutting one film into a lot of films with predetermined sizes quickly, so that the films can be used for stacking semiconductor chips, thereby facilitating the manufacturing processes.

While the invention has been described by way of example and in terms of preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

What is claimed is:

1. A method for manufacturing films used in semiconductor package, comprising the steps of:
providing a frame having an upper surface and a lower surface opposite to the upper surface, a through-hole being formed in the frame;
mounting a first covering layer onto the lower surface of the frame in order to covering the bottom of the through-hole;
placing a film into the through-hole of the frame, the film being adhered onto the first covering layer; and
cutting the film into a plurality of films each having a predetermined size by a cutting tool.

2. The method for manufacturing the films used in semiconductor package according to claim 1, wherein the films are adhered onto the first covering layer.

3. The method for manufacturing the films used in semiconductor package according to claim 1, wherein the film is cut into a predetermined depth so that the films after cut are still adhered onto the first covering layer in the step of cutting the film.

4. The method for manufacturing the films used in semiconductor package according to claim 1, wherein after the film is adhered onto the first covering layer, a second covering layer is further provided for mounting on the upper surface of the frame to cover the film, so that the film is located between the first covering layer and the second covering layer.

5. The method for manufacturing the films used in semiconductor package according to claim 1, wherein the film is adhesive at a side adhered to the first covering layer.

6. The method for manufacturing the films used in semiconductor package according to claim 4, wherein the film is adhesive at a side adhered to the second covering layer in order to adhere the film to the second covering layer.

7. A stacked semiconductor package structure for electrically connecting to a printed circuit board, the package structure comprising:
a substrate having a first surface and a second surface opposite to the first surface, the first surface being formed with signal input terminals, the second surface being formed with signal output terminals for electrically connecting to the printed circuit board;
a lower semiconductor chip having a lower surface and an upper surface opposite to the lower surface, the lower surface being mounted onto the first surface of the substrate, the upper surface being formed with a plurality of bonding pads at its central portion;
two films adhered to the upper surface of the lower semiconductor chip;
a plurality of wirings each electrically connected to a corresponding one of the bonding pads of the lower semiconductor chip at one end, and each electrically connected to a corresponding one of the signal output terminals of the substrate at the other end; and
an upper semiconductor chip mounted on the two films and above the upper surface of the lower semiconductor chip to stack with the lower semiconductor chip.

8. The stacked semiconductor package structure according to claim 7, wherein an adhesive agent is applied to places near the bonding pads of the lower semiconductor chip, so as to adhere the upper semiconductor chip to the lower semiconductor chip.

9. The stacked semiconductor package structure according to claim 7, further comprising a plurality of wirings for electrically connecting the upper semiconductor chip to the signal input terminals of the substrate.

10. The stacked semiconductor package structure according to claim 7, further comprising a package layer on the first surface of the substrate, for packing the lower semiconductor chip and the upper semiconductor chip and protecting the plurality of wirings.
